(19) United States
(12) Patent Application Publication
(10) Pub. No.: US 2010/0148907 A1
(43) Pub. Date: Jun. 17, 2010

(54) CURRENT TRANSFORMER AND ELECTRICAL MONITORING SYSTEM

(75) Inventors: Karim Younsi, Ballston Lake, NY (US); Prabhakar Neti, Niskayuna, NY (US); Charles David Whitefield, II, Minden, NV (US); Yingneng Zhou, Niskayuna, NY (US); Tiziana Bertoncelli, Munchen (DE)

Correspondence Address: GENERAL ELECTRIC COMPANY;GLOBAL RESEARCH, ONE RESEARCH CIRCLE, PATENT DOCKET RM. BLDG. K1-4A59, NISKAYUNA, NY, 12309, US

(73) Assignee: GENERAL ELECTRIC COMPANY, SCHENECTADY, NY (US)

(21) Appl. No.: 12/336,653

(22) Filed: Dec. 17, 2008

(51) Int. Cl. H01F 27/28

(52) U.S. Cl. 336/180

(57) ABSTRACT

A current transformer comprises a magnetic core having a closed central opening, at least two conductors extending through the central opening and positioned symmetrically within the magnetic core, and at least one set of winding turns wound around the core in a balanced configuration with respect to the at least two conductors.

### BACKGROUND

Embodiments of the invention relate to current transformers for measuring a differential current transmitted by at least two conductors, calibration methods for such current transformers, and electrical monitoring systems using such current transformers.

Current transformers are devices used to scale large primary currents to smaller and more easy to measure secondary currents for use in metering and protective relaying in the electrical power industry. A differential current transformer, for example, may be used for measurement of leakage current in an insulation breakdown monitoring system. To improve sensitivity in such current transformers, there is a need for improved current transformers.

### BRIEF DESCRIPTION

Briefly, in accordance with one aspect disclosed herein, a current transformer comprises a magnetic core having a closed central opening, at least two conductors extending through the central opening and positioned symmetrically within the magnetic core, and at least one set of winding turns wound around the core in a balanced configuration with respect to the at least two conductors.

In accordance with another aspect disclosed herein, a calibration method for a current transformer is provided. The current sensor comprises a core with a central opening, at least two conductors extending through the central opening, and a winding on the core. The calibration method comprises transmitting currents through the at least two conductors, obtaining a measured differential current through the winding, and changing a spatial relative position of the at least two conductors and turns of winding with respect to the core to obtain a target reading.

In accordance with still another aspect disclosed herein, an electric monitoring system comprises a current transformer. The current sensor comprises a magnetic core having a closed central opening, at least two conductors of the system to be measured extending through the central opening and positioned symmetrically within the magnetic core, and at least one set of winding turns wound around the core in a balanced configuration with respect to the at least two conductors. The electric monitoring system further comprises a processing module for receiving a measured differential current from the at least one set of winding turns and monitoring the measured differential current.

In accordance with still another aspect disclosed herein, an insulation condition monitoring method for a rotating electric machine is provided. The method comprises calibrating a current transformer by transmitting currents with the same current amplitude and reversed direction through two conductors extending through a central opening of a magnetic core; receiving a measured differential current from a winding on the core; and changing a spatial relative position of the at least two conductors and turns of the of winding with respect to the core to obtain a target reading. The method further comprises measuring a first set of values for an instantaneous differential current using the calibrated current transformer and an instantaneous phase voltage during operation of the machine, calculating a second set of values for a phasor current and a phasor voltage based upon the first set of values of the instantaneous differential current and the instantaneous phase voltage, respectively; calculating an angular relationship between the phasor current and phasor voltage; and determining the insulation condition based on the angular relationship.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic view of a conventional current transformer for measurement of a differential current between currents carried by two conductors.

FIGS. 2-4 are schematic views of current transformers according to different embodiments of the invention.

FIGS. 5 and 6 are equivalent circuits of connections of two set of winding turns in FIGS. 3 and 4, respectively, for measurement of load current and differential current.

FIGS. 7-10 are schematic views of current transformers according to other embodiments of the invention.

FIG. 11 is a block diagram of an insulation monitoring system utilizing a current transformer according to one embodiment of the invention.

FIG. 12 is a block diagram showing a ground fault monitoring system according to one embodiment of the invention.

### DETAILED DESCRIPTION

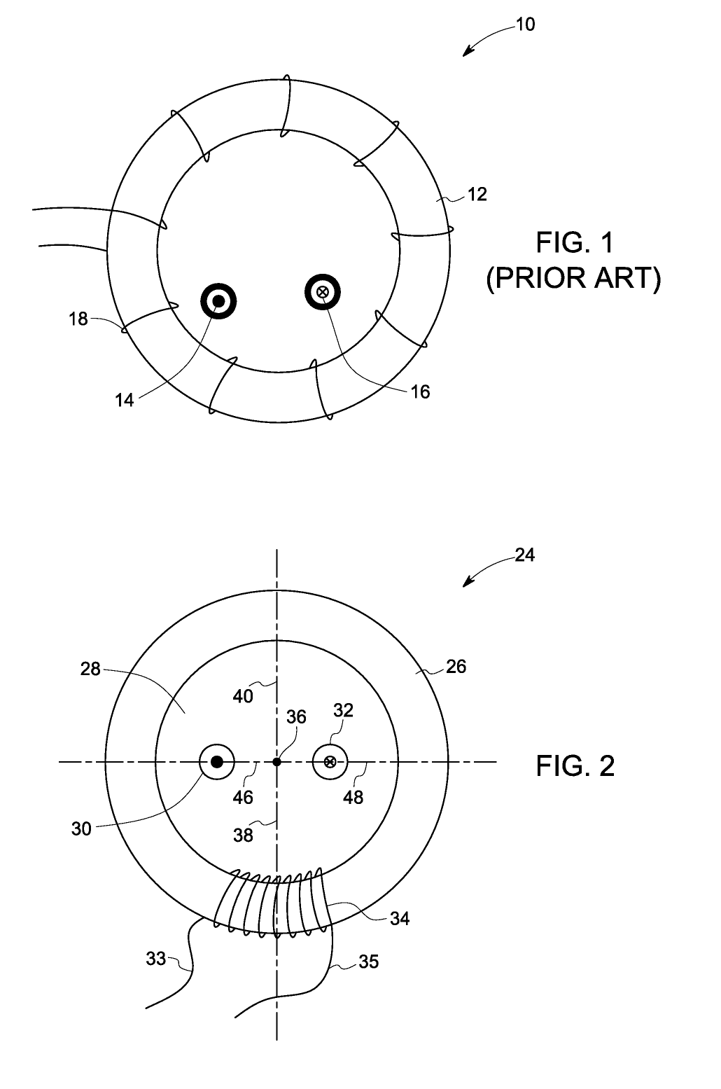

Referring to FIG. 1, a conventional current transformer 10 comprises a core 12 defining a closed central opening, a primary winding including a first and second conductors 14 and 16 extending through the closed central opening, and a secondary winding comprising a plurality of winding turns 18 wrapped on the core 12. Currents carried by the first and second conductors 14 and 16 are directed in opposite directions along a central axis of the core 12, and thus generate opposite magnetic fluxes along the central axis. The current generated on the plurality of winding turns 18 is induced by a difference of the opposite magnetic fluxes, and thus is an indication of the difference of the currents carried on the first and second conductors, which is hereinafter referred to as a “differential current.” Thus, the current transformer 10 is commonly referred to as a “differential current transformer.” As used herein “closed central opening” means that circumferential core portion surrounding the opening is closed without any air gap.

A differential current transformer can be used for measurement of leakage current in an insulation breakdown monitoring system. The currents carried in the first and second conductors 14 and 16 are large and the leakage current measured by the plurality winding turns 18 is very small. As the first and second conductors 14 and 16 and the winding turns 18 are often randomly positioned with respect to each other and with respect to the core 12, the differential magnetic fluxes picked up by individual winding turns 18 at different locations are different and result in error in the measured differential current from the winding turns 18.

Embodiments of the invention relate to a current transformer for measuring a differential current between currents transmitted on at least two conductors. The current transformer comprises a core with a closed central opening, the at least two conductors extending through the closed central opening, and a plurality of windings wound on the core. The at least two conductors represent as a primary winding of the current transformer. Magnetic flux generated by the at least two conductors induces a current on the plurality of windings, and accordingly, the windings represent as a secondary winding of current transformer, and a reading of the current from the windings is a measured “differential current” of the currents carried on at least two conductors. The windings and the at least two conductors are arranged in the core in a balanced configuration. The balanced configuration is advantageous because for improving sensitivity in differential current sensing.

Embodiments of the invention relate to a calibration method for a current transformer to measure a differential current between currents transmitted on at least two conductors. The method comprises extending the at least two conductors through a central opening of a core, winding a plurality of winding turns on the core, transmitting currents through the at least two conductors such that an ideal differential current of the currents is zero, receiving a measured differential current by reading of the winding turns, and changing spatial relative position of the at least to conductors and the windings with respect to the core to obtain a target reading. In one embodiment the target reading comprises the smallest obtainable target reading. In another embodiment, the target reading comprises a reading smaller than a preset value.

Embodiments of the invention additionally relate to electrical monitoring systems and methods using current transformers with the balanced configuration or comprising the calibration method for current transformers. The monitoring systems may include, for example, insulation monitoring systems or ground fault or arc fault detection systems for multi-phase motors, generators, and transformers.

FIGS. 2-4 and 7-10 illustrate current transformers according to several embodiments of the invention, and common elements across different embodiments share the same reference numbers for purposes of simplicity of description. In certain embodiments, the current transformers each include a core having a closed central opening, a number N of conductors extending through the central opening, and at least one set of winding turns wound on the core. The closed central opening is divided by a number N of phantom lines each extending from a center point of the central opening, and each phantom lines is spaced from an adjacent one with an angle of 360/N degrees. In one embodiment, the center point is a center along the direction of the central opening that extending through the first and second conductors. Every two adjacent conductors are symmetric about a corresponding phantom line. In one embodiment, each of the at least one set of winding turns is centered about one of the phantom lines on the magnetic core.

In certain embodiments, the current transformer further includes at least two reference lines respectively extending through the center point of the central opening and a corresponding conductor. In another embodiment, the current transformer comprises a number N of sets of winding turns, and each set of winding turns is centered on a corresponding reference. Thus, windings and conductors are in a balanced configuration in the central opening of the core.

In certain embodiments, current transformers each comprise one or more locking mechanisms for securing windings and/or conductors at the balanced configuration. In certain embodiments, a locking mechanism for windings may comprise a permanent mechanism such as adhesives and banding, or a removable mechanism such as brackets or clamps. In some embodiments, locking mechanisms for conductors may comprise plates or blocks with centering holes. Such plates and/or blocks may be internal or external to the core.

Referring to FIGS. 2-4 and 7, current transformers 24, 224, 324 and 424, according to different embodiments of the invention, each comprise a core 26 defining a closed central opening 28, first and second conductors 30 and 32 extending through the closed central opening 28 and acting as a primary winding of current transformer 24, and windings 34, 42, 44 wound on core 26. Magnetic flux generated by the first and second conductors 30 and 32 induces a current on the windings 34, 42, and 44, and, accordingly, the windings comprise a secondary winding of the current transformer. The windings of each current transformer include a pair of terminals 33 and 35 for electrical coupling to a reading apparatus (not shown) wherein a reading is a measured as a “differential current” of the currents carried on the first and second conductors. In one embodiment, central opening 28 is divided by two phantom lines 38 and 40 into equally two parts. The two phantom lines 38 and 40 extending from a center point 36 of central opening 28 and being spaced from each other by 180 degrees. The first and second conductors 30 and 32 are symmetric about the phantom lines 38 and 40. In one embodiment, currents transmitted through the first and second conductors 30 and 32 are in opposite directions.

In one embodiment, central opening 28 comprises first and second reference lines 46 and 48. First reference line 46 extends through center point 36 and first conductor 30, and second reference line 48 extends through center point 36 and the second conductor 32. In one embodiment, the first and second reference lines 46 and 48 are in line with each other. In other embodiments, such as shown in FIG. 8, the first and second reference lines 46 and 48 are not in line with each other.

In one embodiment, core 26 has a symmetric configuration about at least one of the phantom lines 38 and 40. In certain embodiments, core 26 may be circular, rectangular, square, or a combination thereof. In certain embodiments, core 26 comprises a laminated magnetic steel, a solid magnetic steel, or a sintered magnetic alloy. The overall core diameter may range from 1 cm to 100 cm, for example.

Referring to FIG. 2, an exemplary current transformer 24, according to one embodiment of the invention, includes only one set of winding turns 34. In the illustrated embodiment, the phantom lines 38 and 40 extend through a center of the set of winding turns 34, and the set of winding turns 34 is symmetric about one of the phantom lines 38 and 40. Accordingly, the set of winding turns 34 is at a balanced position with respect to the first and second conductors 30 and 32. Effects of magnetic fluxes generated by the first and second conductors 30 and 32 are symmetric to the set of winding turns 34 in the balanced configuration. In one embodiment, the set of winding turns 34 are compactly wound along a circumferential direction of core 26 with each turn of the set of winding turns 34 being tightly adjacent to another turn, so that the set of winding turns 34 could be more concentrated on phantom line 38.

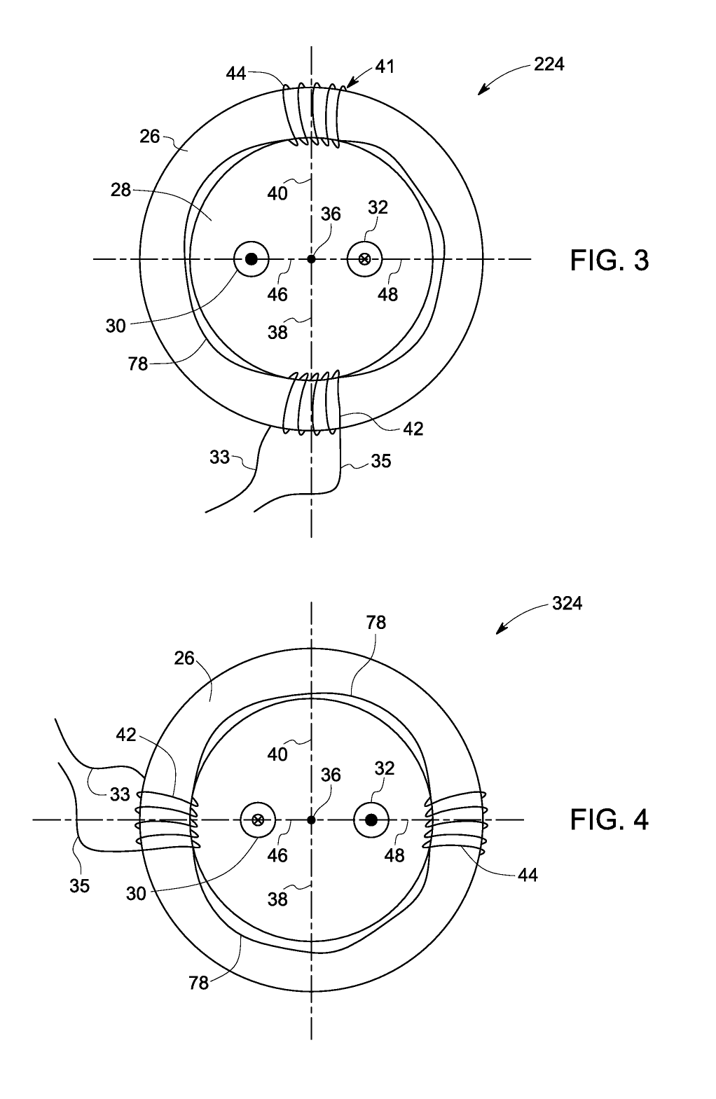

Referring to FIG. 3, an exemplary current transformer 224 according to another embodiment of the invention comprises windings 41 comprising first and second sets of winding turns 42 and 44 wound on core 26. The phantom lines 38 and 40 respectively extend through a center of the first and second sets of winding turns 42 and 44, and the first and second sets of winding turns are respectively symmetric about the phantom lines 38 and 40. The first and second conductors 30 and 32 are symmetric about the phantom lines 48 and 40, and thus effects of the magnetic fluxes generated by the first and second conductors 30 and 32 have balanced effects to each of the first and second sets of winding turns 42 and 44. In one embodiment, each of the first and second sets of winding turns 40 and 42 are compactly wound along a circumferential direction of core 26 to be more concentrated on phantom lines 38 and 40.

FIG. 4 illustrates current transformer 324 according to still another embodiment of the invention. First and second sets of winding turns 42 and 44 are wound on core 26 and are respectively centered on corresponding reference lines 46 and 48.

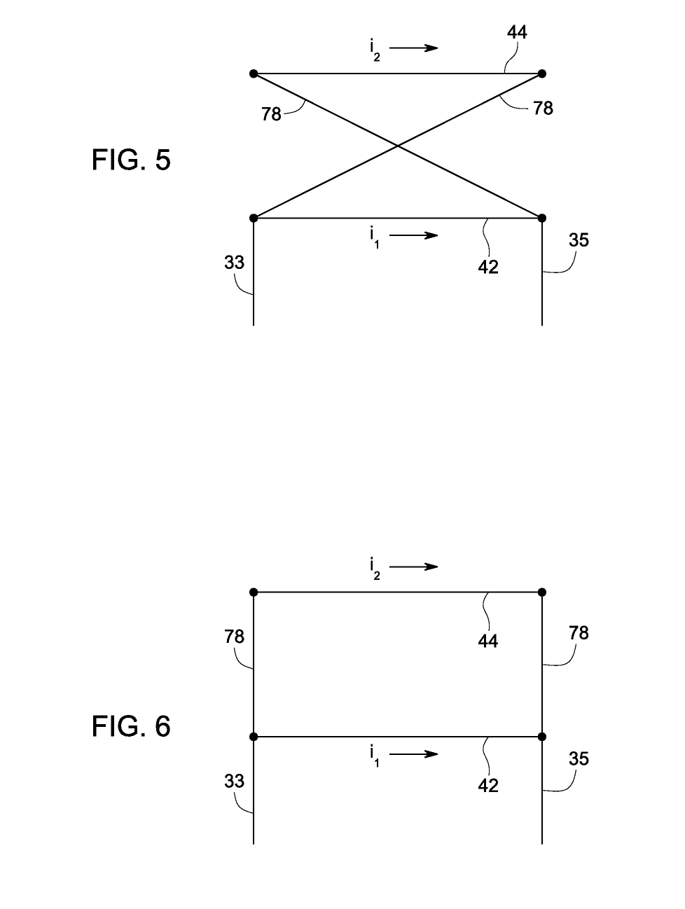

In one embodiment, differential current is measured at terminals 33 and 35 which are electrically coupled to one of the sets of first and second winding turns 42 and 44, and the first and second sets of winding turns are electrically connected to each other via electrical couplers 78. In another embodiment, electrical couplers 78 may comprise the same wire used for the winding turns. FIGS. 5 and 6 are respectively equivalent circuits of a differential current from first and second sets of winding turns 42 and 44. Referring to FIG. 5, in one embodiment, the first and second sets of winding turns 42 and 44 is electrically coupled in series and thus a measurement from the terminals 33 and 35 is an indication of load current of the first and second conductors 30 and 32. Referring to FIG. 6, in another embodiment, wherein the winding turn sets are coupled in parallel, and a measurement from the terminals 33 and 35 is an indication of differential current of the first and second conductors 30 and 32.

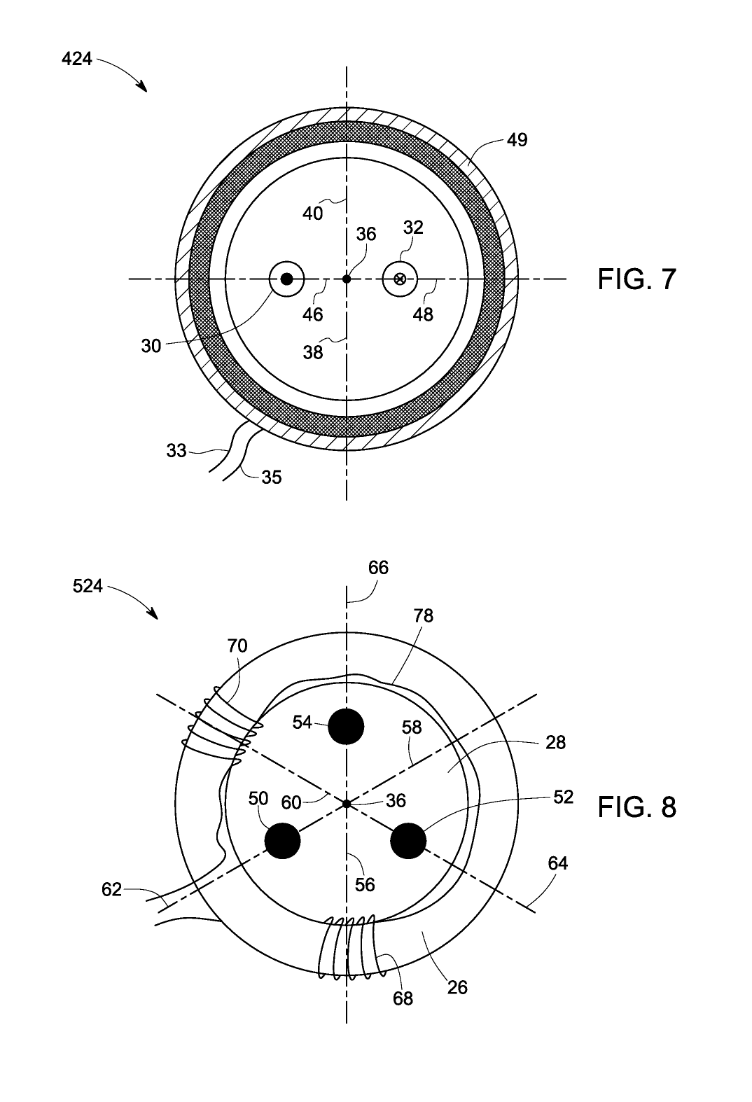

Referring to FIG. 7, a current transformer 424, according to still another embodiment of the invention, comprises one set of winding turns 49 evenly distributed on the core 26. In one embodiment, the set of winding turns 49 having a plurality of winding turns each tightly abuts with an adjacent one along the core 26. First and second conductors 30 and 32, symmetrical about the phantom lines 38 and 40, have balanced effects on the winding turns.

FIGS. 8-10 illustrate current transformers 524, 624 and 724 according to different embodiments of the invention. The current transformers each comprise a core 26 defining a closed central opening 28, first, second, and third conductor 50, 52, and 54 extending through the closed central opening 28 and acting as a primary winding, and windings comprising winding turns 68, 70, 72, 74, 76 wound on core 26. Magnetic flux generated by first, second and third conductors 50, 52 and 54 induces a current on the windings, and accordingly, the windings acts as a secondary winding of the current transformer, and a reading of the current from the windings is a “differential current” of the currents carried on the first, second and third conductors 50, 52 and 54. In one embodiment, central opening 28 is divided equally into three parts by three phantom lines 56, 58, and 60. The three phantom lines 56, 58, and 60 each extend through center point 36, and are spaced from one another by 120 degrees. Every two of the first, second and third conductors 50, 52, and 54 are symmetric about a corresponding phantom line. In one embodiment, currents transmitted through the first, second, and third conductors 50, 52, and 54 are alternating currents with different phase angles.

In one embodiment, central opening 28 comprises first, second, and third reference lines 62, 64, and 66, which are spaced from one another by 120 degrees. First reference line 62 extends through center point 36 and first conductor 50, second reference line 64 extends through center point 36 and the second conductor 52, and third reference line 64 extends through center point 36 and the second conductor 54.

Referring to FIG. 8, current transformer 524, according to one embodiment of the invention, comprises first and second sets of winding turns 68 and 70. The first and second sets of winding turns 68 and 70 are wound on core 26 and are respectively centered on a corresponding phantom line (shown as line 60 for purposes of example).

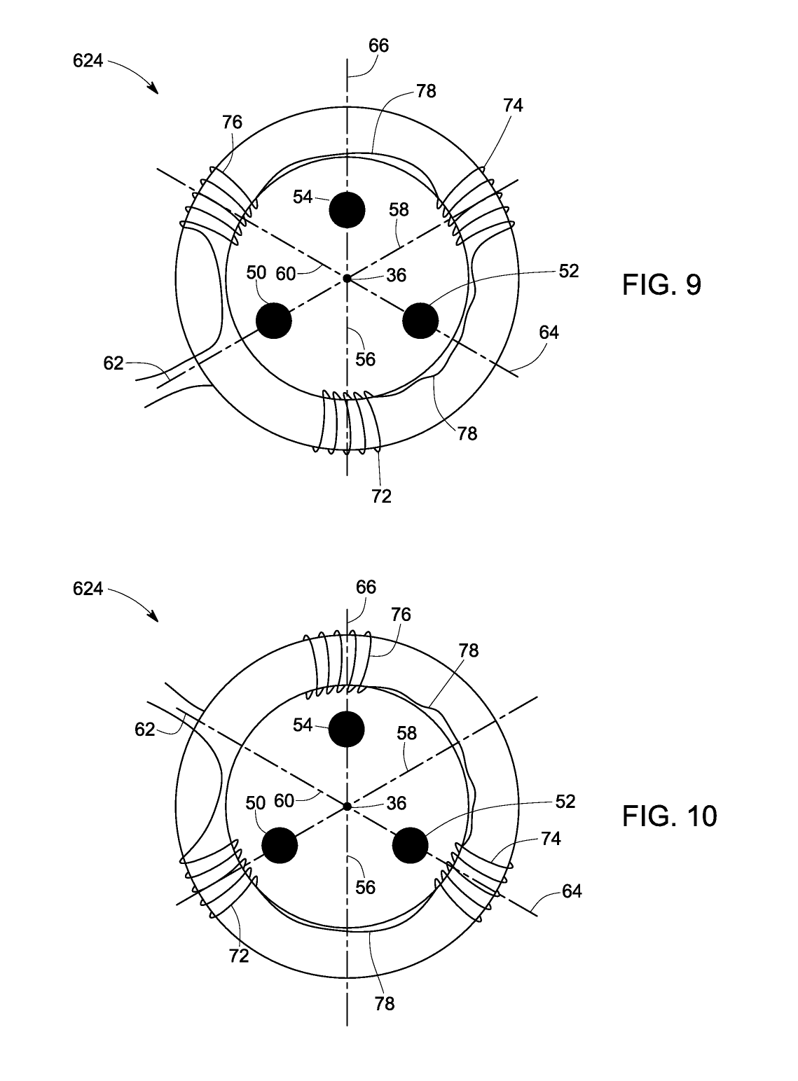

Referring to FIG. 9, current transformer 624, according to another embodiment of the invention, comprises first, second, and third sets of winding turns 72, 74, and 76 wound on core 26. The first, second and third sets of winding turns 72, 74, and 76 are wound on core 26 and are each respectively centered on a corresponding phantom line 56, 58 and 60.

FIG. 10 illustrates current transformer 724, according to still another embodiment of the invention, in which first, second, and third sets of winding turns 72, 74 and 76 are each centered on a corresponding reference line 62, 64, and 66.

In one embodiment, a calibration method for a current transformer, comprises providing at least two conductors through a central opening of a core and a winding on the core, transmitting currents through the at least two conductors, receiving a measured differential current by reading of the windings, and changing spatial relative position of the at least two conductors and the windings with respect to the core to obtain a target reading. The target reading which may be a minimum reading or a reading smaller than a preset value. In one embodiment, at least one of the conductors is moved in a circumferential direction for obtaining the targeted reading. In another embodiment, wherein the windings are wound in a moveable manner, individual turns of the windings are moved along the core to obtain the targeted reading. In still another embodiment, the core is moved in an up-down direction, or in a radial direction to obtain the targeted reading.

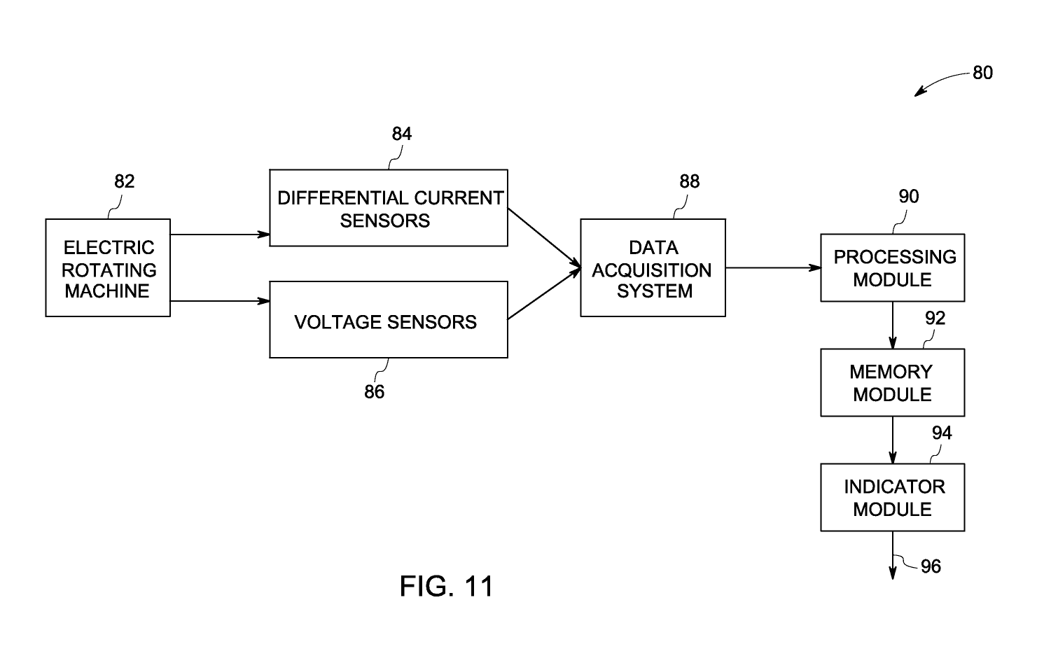

FIG. 11 illustrates an electric monitoring system utilizing a current transformer according to one embodiment of the invention. The illustrated electric monitoring system is an online insulation condition monitoring system 80 for a rotating electric machine 82, which is typically a motor or a generator. The system 80 comprises a current sensor 84 and a voltage sensor 86 coupled to the machine 82, for measuring values of instantaneous differential current and the instantaneous phase voltage respectively. A data acquisition system 88 enables measurement of signals from the output of the differential current sensor 84 and the voltage sensor 86. The signals are digitized at a sampling frequency sufficient for obtaining the phasor quantities.

The signals from the sensors 84 and 86, measured by the data acquisition system 88, are applied to a processing module 90. Module 90 will typically include hardware circuitry and software for performing computations indicative of insulation condition as described below. Module 90 may thus include a range of circuitry types, such as, a microprocessor based module, and application-specific or general purpose computer, programmable logic controller, or even a logical module or code within such a device. The module 90 is configured to convert the values for the instantaneous differential current and the instantaneous phase voltage to respective values for phasor current and phasor voltage. The processing module 90 further calculates an angular relationship between phasor current and phasor voltage and generates an output based on the calculated angular relationship, as an indication of insulation condition. A memory module 92 is used for storing the output generated from the processing module 90. The same, or a different memory module may also store programming code, as well as parameters and values required for the calculations made by the processing module 90. An indicator module 94 compares the output of the processing module 90 to a predetermined threshold value and generates an indication signal 96 based on the comparison. In general, the indication signal 96 may provide a simple status output, or may be used to activate or set a flag, such as an alert when the output of the processing module 90 exceeds the threshold value, indicating that the insulation is in need of attention or will be in need of attention based upon its current state or a trend in its state. The method of calculating insulation condition from the measured differential current and phasor voltage may be of the type described by Younsi et al., U.S. Pub. No. 2005/0218906A1, the disclosure of which is incorporated herein by reference.

The current sensors are differential current sensors configured to generate feedback signals representative of instantaneous differential current through each machine winding. Similarly, the voltage sensors are adapted to measure the instantaneous phase voltage across the machine windings and corresponding neutral point. Output from the sensors is provided to the data acquisition system 88, and there through, to the processing module 90. As discussed below, based upon these sensed parameters, processing module 90 evaluates the condition of insulation of the machine windings.

In one embodiment, the current sensors each comprises a current transformer as described above with reference to FIGS. 2-4 and 7 having a balanced configuration, which ensures an accurate measurement, and enable a practical online insulation monitoring. In an alternative embodiment, a conventional current transformer with an unbalanced conductor and winding arrangement on a core is used as a current sensor, and an insulation monitoring method comprises a calibration step for converting the unbalanced transformer into a balanced conductor and winding configuration as described above.

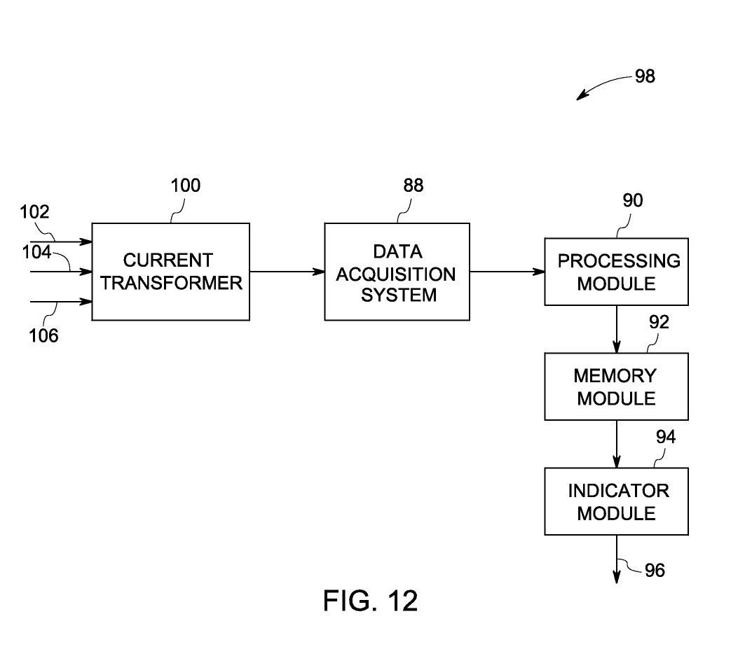

FIG. 12 illustrates an electric monitoring system including a current transformer according to another embodiment of the invention. The illustrated electric monitoring system is a ground fault monitoring system 98 for providing ground fault protection for electronic equipment products. In certain embodiments, ground fault monitoring system 98 comprises a current transformer 100 for measurement of differential current of three conductors 102, 104 and 106. The system 98 may further comprise data acquisition system for 88 obtaining the differential current, a processing module 90 performing computations, memory module 92 for storing the output generated from the processing module 90, an indicator module 94 compares the output of the processing module 90 to a predetermined threshold value and generates an indication signal 96 based on the comparison.

In one embodiment, the current sensor comprises a current transformer as described above with reference to FIGS. 8-10 having a balanced configuration, which ensures an accurate measurement and enables practical online insulation monitoring. In an alternative embodiment, a conventional current transformer with an unbalanced conductor and winding arrangement on a core is used as a current sensor, and an ground fault monitoring method comprises a calibration step for calibrating the current transformer with a balanced conductor and winding configuration as described above. In one embodiment, the calibration method comprising transmitting currents through the three conductors, and the currents are sine wave signals with the same current amplitude and with phases spaced from one another by 120 degrees. Relative spatial relationship of the conductors with the windings is changed in the core until a minimum reading or a reading smaller than a set value is obtained. In one embodiment, one of, or two of, or three of the conductors is moved in a circumferential direction for obtaining the targeted reading. In another embodiment, individual winding turns are moved along the core to obtain the targeted reading. In still another embodiment, the core is moved in an up-down direction, or in a radial direction to obtain the targeted reading.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A current transformer comprising:
a magnetic core having a closed central opening;
at least two conductors extending through the central opening and positioned symmetrically within the magnetic core; and
at least one set of winding turns wound around the core in a balanced configuration with respect to the at least two conductors.

2. The current transformer according to claim 1, wherein the at least two conductors comprise N conductors, wherein the central opening comprises N phantom lines evenly spaced apart and each extending outward from a center portion of the central opening, and wherein every pair of the N conductors is symmetric about one of the phantom lines.

3. The current transformer according to claim 2, wherein the central opening comprises N reference lines each extending from the center portion of the central opening, each reference line extending through a respective one of the N conductors.

4. The current transformer according to claim 3, wherein the at least one set of winding turns is symmetric about one of the phantom lines.

5. The current transformer according to claim 4, wherein N comprises two, and wherein currents transmitted through the two conductors are in opposite directions.

6. The current transformer according to claim 5, wherein the at least one set of winding turns comprises one set of winding turns centered on one of the phantom lines.

7. The current transformer according to claim 5, wherein the at least one set of winding turns comprises two set of winding turns respectively centered on two reference lines.

8. The current transformer according to claim 5, wherein the at least one set of winding turns comprises two set of winding turns respectively centered on two phantom lines.

9. The current transformer according to claim 1, wherein the at least one set of winding turns comprises a plurality of winding turns tightly abutting one another along the core.

10. The current transformer according to claim 4, wherein the at least two conductors comprise three conductors, and currents transmitted by the three conductors are alternating circuits having different phase angles.

11. The current transformer according to claim 10, wherein the at least one set of winding turns comprises two set of winding turns each being centered one of the phantom lines.

12. The current transformer according to claim 10, wherein the at least one set of winding turns comprises three set of winding turns each being centered on a corresponding phantom line.

13. The current transformer according to claim 10, wherein the at least one set of winding turns comprises three set of winding turns each being centered on a corresponding reference line.

14. A calibration method for a current transformer comprising a core with a central opening, at least two conductors extending through the central opening, and a winding on the core, the calibration method comprising:
transmitting currents through the at least two conductors;
obtaining a measured differential current through the winding; and
changing a spatial relative position of the at least two conductors and turns of winding with respect to the core to obtain a target reading.

15. The calibration method according to claim 14, wherein transmitting currents through the at least two conductors comprises transmitting currents in two conductors with the same amplitude and revered direction.

16. The calibration method according to claim 14, wherein transmitting currents through the at least two conductors comprises transmitting alternating currents through three conductors, the alternating currents having the same current amplitude and phase angles shifted 120 degrees with one another.

17. The calibration method according to claim 14, wherein changing the spatial relative position comprises changing a position of at least one of the conductors.

18. The calibration method according to claim 14, wherein changing the spatial relative position comprises changing positions of winding turns along a circumferential direction of the core.

19. The calibration method according to claim 14, wherein changing the spatial relative position comprises moving the core in a circumferential direction or in a linear direction.

20. An electric monitoring system, comprising:
a current transformer comprising:
a magnetic core having a closed central opening;
at least two conductors of the system to be measured extending through the central opening and positioned symmetrically within the magnetic core; and
at least one set of winding turns wound around the core in a balanced configuration with respect to the at least two conductors; and
a processing module for receiving a measured differential current from the at least one set of winding turns and monitoring the measured differential current.

21. The system according to claim 20, wherein the system to be measured comprises a rotating electrical machine, further comprising a voltage sensor coupled to the rotating electric machine for measuring values of instantaneous phase voltage, wherein the processing module is coupled to the current sensor and the voltage sensor and configured for converting the values for instantaneous differential current and instantaneous phase voltage to respective values for phasor current and phasor voltage, and wherein the processing module is further configured to calculate an angular relationship between the phasor current and phasor voltage and to generate an output based on the angular relationship as an indication of insulation condition.

22. The system according to claim 20, wherein the at least two conductors comprises three conductors, and wherein the processing module is configured to calculate a ground fault condition.

23. The system according to claim 20, wherein the at least one set of winding turns is symmetric about one of the phantom lines on the core.

24. The system according to claim 20, wherein the closed central opening comprises two reference lines, each reference line extending through the center point of central opening and a corresponding conductor, and each set of winding turns being centered on a corresponding reference line.

25. An insulation condition monitoring method for a rotating electric machine, the method comprising:
calibrating a current transformer by transmitting currents with the same current amplitude and reversed direction through two conductors extending through a central opening of a magnetic core, receiving a measured differential current from a winding on the core, and changing a spatial relative position of the at least two conductors and turns of the of winding with respect to the core to obtain a target reading;
measuring a first set of values for an instantaneous differential current using the calibrated current transformer and an instantaneous phase voltage during operation of the machine;
calculating a second set of values for a phasor current and a phasor voltage based upon the first set of values of the instantaneous differential current and the instantaneous phase voltage, respectively;
calculating an angular relationship between the phasor current and phasor voltage; and determining the insulation condition based on the angular relationship.
